(19) United States
(12) Patent Application Publication
(10) Pub. No.: US 2025/0239978 A1
(43) Pub. Date: Jul. 24, 2025

(54) AUDIO PROCESSING CIRCUIT

(71) Applicant: Realtek Semiconductor Corp., HsinChu (TW)

(72) Inventors: Chia-Ling Chang, HsinChu (TW); Fu-Yi Hsieh, HsinChu (TW); Sheng-Tsung Wang, HsinChu (TW); Pei-Chun Liao, HsinChu (TW)

(73) Assignee: Realtek Semiconductor Corp., HsinChu (TW)

(21) Appl. No.: 19/019,350

(22) Filed: Jan. 13, 2025

(30) Foreign Application Priority Data
Jan. 24, 2024 (TW) 113102700

(51) Int. Cl. H03G 3/30; H04R 3/00

(52) U.S. Cl. CPC H03G 3/301; H03G 3/3089; H04R 3/00

(57) ABSTRACT

An audio processing circuit includes a first amplifier, a processing circuit, an analog-to-digital converter, a peak value detection circuit, and a control circuit. The first amplifier receives a first input signal, and performs an amplification operation upon the first input signal to generate a first amplified input signal. The processing circuit processes the first amplified input signal to generate a processed signal. The analog-to-digital converter performs an analog-to-digital conversion operation upon the processed signal to generate a digital signal. The peak value detection circuit detects a peak value of the first amplified input signal, a peak value of the processed signal, or a peak value of the digital signal, in order to generate a peak value detection result. The control circuit controls a gain value of the first amplifier and a gain value of the processing circuit according to the peak value detection result.

### BACKGROUND OF THE INVENTION

### 1. Field of the Invention

The present invention is related to audio processing, and more particularly, to an audio processing circuit that can have a good signal-to-noise ratio (SNR) without increasing both a current and a transistor size of an analog-to-digital converter (ADC).

### 2. Description of the Prior Art

An audio processing circuit requires setting an ADC for converting an analog signal into a digital signal, such that a subsequent digital signal processor can perform related operations. An SNR of the audio processing circuit is mainly limited by the ADC. If the SNR requires improvement, a current and a transistor size of the ADC must be increased, which may increase power consumption of the audio processing circuit and may increase chip area.

### SUMMARY OF THE INVENTION

It is therefore one of the objectives of the present invention to provide an audio processing circuit that can have a good SNR without increasing both a current and a transistor size of an ADC, in order to address the above-mentioned issues.

According to an embodiment of the present invention, an audio processing circuit is provided. The audio processing circuit comprises a first amplifier, a processing circuit, an ADC, a peak value detection circuit, and a control circuit. The first amplifier is arranged to receive a first input signal, and perform an amplification operation upon the first input signal to generate a first amplified input signal. The processing circuit is coupled to the first amplifier, and is arranged to process the first amplified input signal to generate a processed signal. The ADC is coupled to the processing circuit, and is arranged to perform an analog-to-digital conversion operation upon the processed signal to generate a digital signal. The peak value detection circuit is arranged to detect a peak value of the first amplified input signal, a peak value of the processed signal, or a peak value of the digital signal, in order to generate a peak value detection result. The control circuit is arranged to control a gain value of the first amplifier and a gain value of the processing circuit according to the peak value detection result.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating an audio processing circuit according to an embodiment of the present invention.

FIG. 2 is a diagram illustrating an audio processing circuit according to another embodiment of the present invention.

### DETAILED DESCRIPTION

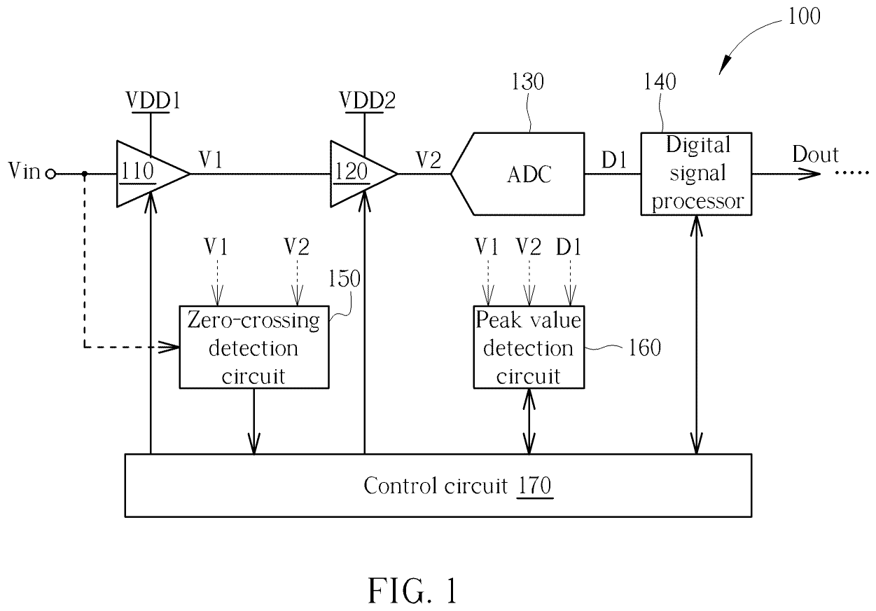

FIG. 1 is a diagram illustrating an audio processing circuit 100 according to an embodiment of the present invention. As shown in FIG. 1, the audio processing circuit 100 includes an amplifier 110, a processing circuit 120, an analog-to-digital converter (ADC) 130, a digital signal processor 140, a zero-crossing detection circuit 150, a peak value detection circuit 160, and a control circuit 170. In this embodiment, the amplifier 110 may be a programmable gain amplifier (PGA). The processing circuit 120 may be an amplifier that provides different gains including negative gains. The audio processing circuit 100 is arranged to receive and process an input signal Vin, wherein the input signal Vin may be an audio signal from a microphone or other audio sources.

The amplifier 110 receives the input signal Vin, and performs a signal amplification operation upon the input signal Vin to generate an amplified input signal V1. The processing circuit 120 processes (e.g., performs a signal attenuation operation upon) the amplified input signal V1 to generate a processed signal V2. The ADC 130 performs an analog-to-digital conversion operation upon the processed signal V2 to generate a digital signal D1. In this embodiment, the digital signal D1 includes main components and noise components. Since proportions of the main components and the noise components are not the same during amplification and attenuation operations, the digital signal D1 will have a better signal-to-noise ratio (SNR) compared to a digital signal without amplification and attenuation operations.

In an embodiment, a supply voltage of the amplifier 110 is a supply voltage VDD1, and a supply voltage of the processing circuit 120 and the ADC 130 is a supply voltage VDD2, wherein the supply voltage VDD2 is less than the supply voltage VDD1. Thus, under a situation that the amplifier 110 has the higher supply voltage VDD1, the input signal Vin and the amplified input signal V1 may have a larger dynamic range for improving the SNR. In addition, the processing circuit 120 may provide negative gains to reduce a voltage level of the amplified input signal V1 in order to generate the processed signal V2, such that the intensity/voltage level of the input signal Vin can be more consistent with that of the processed signal V2 (please note this is not meant to be a limitation of the present invention); the waveform clamping distortion caused by the amplifier 110 having the higher supply voltage VDD1 can thereby be avoided, wherein the amplifier 110 having the higher supply voltage VDD1 causes the highest voltage level of the amplified input signal V1 to exceed the supply voltage VDD2 of the ADC 130. In some embodiments, the supply voltage VDD1 may be equal to or less than the supply voltage VDD2.

The digital signal processor 140 processes the digital signal D1 to generate and transmit a processed digital signal Dout to a back-end circuit. In an embodiment, the digital signal processor 140 may perform gain adjustment upon the digital signal D1 in order to adjust an intensity of the digital signal D1 (e.g., volume of the audio signal). Specifically, if the amplifier 110 performs a signal amplification operation upon the input signal Vin to increase the amplitude/intensity of the input signal Vin, the processing circuit 120 and the digital signal processor 140 may perform a signal attenuation operation upon the amplified input signal V1 and the digital signal D1, respectively, in order to make an intensity of the processed digital signal Dout be consistent with that of the input signal Vin (e.g., the represented audio signals are similar or even identical in volume). It should be noted that the above description wherein the intensity of the processed digital signal Dout is consistent with that of the input signal Vin is for illustrative purposes only, and is not meant to be a limitation of the present invention. In some embodiments, the intensity of the processed digital signal Dout may not be consistent with that of the input signal Vin. In addition, since the noise components in the digital signal D1 may be attenuated by the negative gains provided by the digital signal processor 140, the SNR of the processed digital signal Dout can be improved.

The peak value detection circuit 160 may detect a peak value of the amplified input signal V1 (e.g., the highest voltage value), a peak value of the processed signal V2, or a peak value of the digital signal D1, in order to generate a peak value detection result. The control circuit 170 may determine how to adjust gain values of the amplifier 110, the processing circuit 120, and the digital signal processor 140 according to the peak value detection result. For example, when the peak value detection result indicates the amplified input signal V1, the processed signal V2, or the digital signal D1 has a lower first peak value, the control circuit 170 may increase the gain value of the amplifier 110, and control the gain values of the processing circuit 120 and the digital signal processor 140 in order to make an intensity of the processed digital signal Dout be consistent with that of the input signal Vin. When the peak value detection result indicates the amplified input signal V1, the processed signal V2, or the digital signal D1 has a higher second peak value that is higher than the first peak value, the control circuit 170 may decrease the gain value of the amplifier 110, and control the gain values of the processing circuit 120 and the digital signal processor 140 in order to make the intensity of the processed digital signal Dout be consistent with that of the input signal Vin.

The zero-crossing detection circuit 150 detects a zero-crossing point of the input signal Vin (i.e., a time point at which a voltage value of the input signal Vin is the same as a common voltage level), a zero-crossing point of the amplified input signal V1, or a zero-crossing point of the processed signal V2, in order to generate a zero-crossing point detection result. The control circuit 170 may determine a time point at which the gain values of the amplifier 110, the processing circuit 120, and the digital signal processor 140 are adjusted according to the zero-crossing point detection result. Specifically, according to the zero-crossing point detection result, the control circuit 170 may adjust the gain value of the amplifier 110, the gain value of the processing circuit 120, and the gain value of the digital signal processor 140 based on the peak value detection result when the input signal Vin, the amplified input signal V1, or the processed signal V2 is at the zero-crossing point.

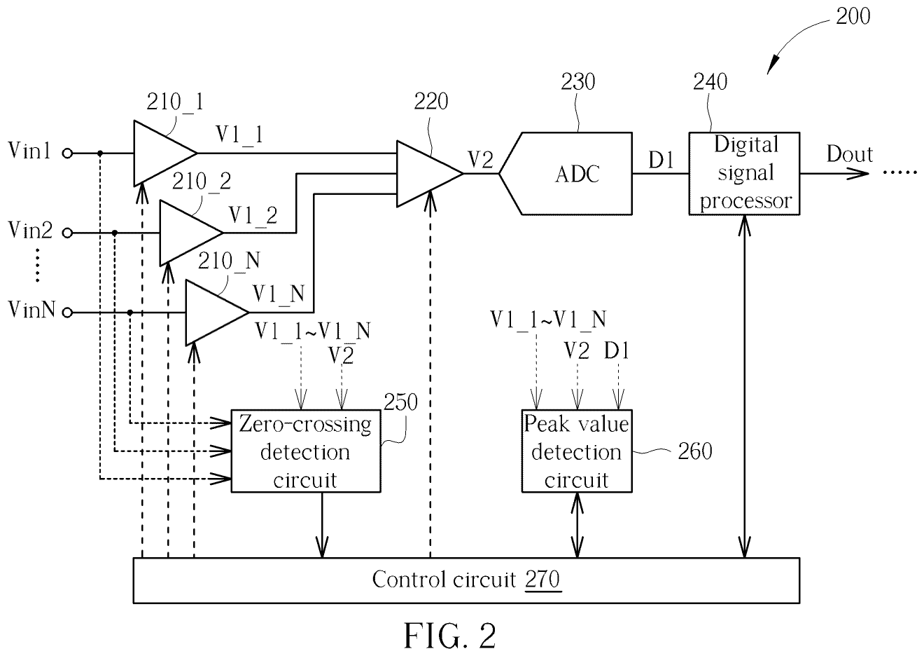

FIG. 2 is a diagram illustrating an audio processing circuit 200 according to another embodiment of the present invention. As shown in FIG. 2, the audio processing circuit 200 includes multiple amplifiers 210_1-210_N, a processing circuit 220, an ADC 230, a digital signal processor 240, a zero-crossing detection circuit 250, a peak value detection circuit 260, and a control circuit 270, wherein “N” may be a positive integer greater than or equal to two. In this embodiment, one or more amplifiers among the amplifiers 210_1-210_N may be PGAs. The processing circuit 220 may include adders and an amplifier that provides different gains including negative gains, or may include a multiplexer (MUX) for outputting one of multiple received inputs. The audio processing circuit 200 is arranged to receive and process multiple input signals Vin1-VinN, wherein the input signals Vin1-VinN may be audio signals from multiple microphones or other audio sources.

The amplifiers 210_1-210_N receive the input signals Vin1-VinN and perform a signal amplification operation upon the input signals Vin1-VinN, respectively, in order to generate multiple amplified input signals V1_1-V1_N. The processing circuit 220 performs an addition operation and gain adjustment (e.g., a signal attenuation operation with negative gains) upon the amplified input signals V1_1-V1_N to generate a processed signal V2. The ADC 230 performs an analog-to-digital conversion operation upon the processed signal V2 to generate a digital signal D1. In this embodiment, the digital signal D1 includes main components and noise components. Since proportions of the main components and the noise components are not the same during amplification and attenuation operations, the digital signal D1 will have a better SNR compared to a digital signal without amplification and attenuation operations.

In an embodiment, a supply voltage of the amplifiers 210_1-210_N is higher than that of the processing circuit 220 and the ADC 230. Thus, under a situation that the amplifiers 210_1-210_N have a higher supply voltage, the input signals Vin1-VinN and the amplified input signals V1_1-V1_N may have a larger dynamic range for improving the SNR. In addition, the processing circuit 220 may provide negative gains to reduce voltage levels of the amplified input signals V1_1-V1_N in order to generate the processed signal V2, such that the intensities/voltage levels of the input signals Vin1-VinN can be more consistent with that of the processed signal V2 (although this is not meant to be a limitation of the present invention); the waveform clamping distortion caused by the amplifiers 210_1-210_N having a higher supply voltage can thereby be avoided, wherein the amplifiers 210_1-210_N having the higher supply voltage cause the highest voltage level of the amplified input signals V1_1-V1_N to exceed the supply voltage of the ADC 230.

The digital signal processor 240 processes the digital signal D1 to generate and transmit a processed digital signal Dout to a back-end circuit. In an embodiment, the digital signal processor 240 may perform gain adjustment upon the digital signal D1 in order to adjust an intensity of the digital signal D1 (e.g., volume of the audio signal). Specifically, if the amplifiers 210_1-210_N perform signal amplification operations upon the input signals Vin1-VinN to increase the amplitude/intensities of the input signals Vin1-VinN, the processing circuit 220 and the digital signal processor 240 may perform a signal attenuation operation upon the amplified input signals V1_1-V1_N and the digital signal D1, respectively, in order to make an intensity of the processed digital signal Dout be consistent with that of the input signals Vin1-VinN (e.g., the represented audio signals are similar or even identical in volume). It should be noted that the above description wherein the intensity of the processed digital signal Dout is consistent with that of the input signals Vin1-VinN is for illustrative purposes only, and is not meant to be a limitation of the present invention. In some embodiments, the intensity of the processed digital signal Dout may not be consistent with that of the input signals Vin1-VinN. In addition, since the noise components in the digital signal D1 may be attenuated by the negative gains provided by the digital signal processor 240, the SNR of the processed digital signal Dout can be improved.

The peak value detection circuit 260 may detect peak values of the amplified input signals V1_1-V1_N, a peak value of the processed signal V2, or a peak value of the digital signal D1, in order to generate a peak value detection result. The control circuit 270 may determine how to adjust gain values of the amplifiers 210_1-210_N, the processing circuit 220, and the digital signal processor 240 according to the peak value detection result. For example, when the peak value detection result indicates the amplified input signals V1_1-V1_N, the processed signal V2, or the digital signal D1 has a lower first peak value, the control circuit 270 may increase the gain values of the amplifiers 210_1-210_N, and control the gain values of the processing circuit 220 and the digital signal processor 240 in order to make an intensity of the processed digital signal Dout be consistent with that of the input signals Vin1-VinN. When the peak value detection result indicates the amplified input signals V1_1-V1_N, the processed signal V2, or the digital signal D1 has a higher second peak value that is higher than the first peak value, the control circuit 270 may decrease the gain values of the amplifiers 210_1-210_N, and control the gain values of the processing circuit 220 and the digital signal processor 240 in order to make the intensity of the processed digital signal Dout be consistent with that of the input signals Vin1-VinN.

The zero-crossing detection circuit 250 detects zero-crossing points of the input signals Vin1-VinN (i.e., time points at which voltage values of the input signals Vin1-VinN are the same as a common voltage level), zero-crossing points of the amplified input signals V1_1-V1_N, or a zero-crossing point of the processed signal V2, in order to generate a zero-crossing point detection result. The control circuit 270 may determine a time point at which the gain values of the amplifiers 210_1-210_N, the processing circuit 220, and the digital signal processor 240 are adjusted according to the zero-crossing point detection result. Specifically, according to the zero-crossing point detection result, the control circuit 270 may adjust the gain values of the amplifiers 210_1-210_N, the gain value of the processing circuit 220, and the gain value of the digital signal processor 240 based on the peak value detection result when the input signals Vin1-VinN are at the zero-crossing points, the amplified input signals V1_1-V1_N are at the zero-crossing points, or the processed signal V2 is at the zero-crossing point. In an embodiment, if the processing circuit 220 is a MUX, the zero-crossing detection circuit 250 may detect the zero-crossing points of the input signals Vin1-VinN, the zero-crossing points of the amplified input signals V1_1-V1_N, or the zero-crossing point of the processed signal V2, in order to generate the zero-crossing point detection result. In addition, if the processing circuit 220 is an adder, the zero-crossing detection circuit 250 may detect the zero-crossing point of the processed signal V2 to generate the zero-crossing point detection result.

In an embodiment, one or more amplifiers among the amplifiers 210_1-210_N shown in FIG. 2 may be selected to operate, and the remaining amplifiers may be turned off. For example, the control circuit 270 may only enable the amplifier 210_1, and turn off the amplifiers 210_2-210_N. At this moment, the operations of the audio processing circuit 200 are similar to that of the audio processing circuit 100 shown in FIG. 1.

In this way, the audio processing circuit of the present invention can have a good SNR without increasing both a current and a transistor size of an ADC, thus solving the issues of the related art.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An audio processing circuit, comprising:
a first amplifier, arranged to receive a first input signal, and perform an amplification operation upon the first input signal to generate a first amplified input signal;
a processing circuit, coupled to the first amplifier, and arranged to process the first amplified input signal to generate a processed signal;
an analog-to-digital converter, coupled to the processing circuit, and arranged to perform an analog-to-digital conversion operation upon the processed signal to generate a digital signal;
a peak value detection circuit, arranged to detect a peak value of the first amplified input signal, a peak value of the processed signal, or a peak value of the digital signal, in order to generate a peak value detection result; and
a control circuit, arranged to control a gain value of the first amplifier and a gain value of the processing circuit according to the peak value detection result.

2. The audio processing circuit of claim 1, wherein the processing circuit is arranged to perform a signal attenuation operation upon the first amplified input signal to generate the processed signal.

3. The audio processing circuit of claim 1, further comprising:
a digital signal processor, coupled to the analog-to-digital converter, and arranged to process the digital signal to generate a processed digital signal;
wherein when the peak value detection result indicates the first amplified input signal, the processed signal, or the digital signal has a first peak value, the control circuit increases the gain value of the first amplifier, and controls the gain value of the processing circuit in order to make an intensity of the processed digital signal be consistent with an intensity of the first input signal; and when the peak value detection result indicates the first amplified input signal, the processed signal, or the digital signal has a second peak value higher than the first peak value, the control circuit decreases the gain value of the first amplifier, and controls the gain value of the processing circuit in order to make the intensity of the processed digital signal be consistent with the intensity of the first input signal.

4. The audio processing circuit of claim 3, wherein the digital signal processor performs a signal attenuation operation upon the digital signal to generate the processed digital signal.

5. The audio processing circuit of claim 4, wherein when the peak value detection result indicates the first amplified input signal, the processed signal, or the digital signal has the first peak value, the control circuit increases the gain value of the first amplifier, and controls the gain value of the processing circuit and a gain value of the digital signal processor in order to make the intensity of the processed digital signal be consistent with the intensity of the first input signal; and when the peak value detection result indicates the first amplified input signal, the processed signal, or the digital signal has the second peak value, the control circuit decreases the gain value of the first amplifier, and controls the gain value of the processing circuit and the gain value of the digital signal processor in order to make the intensity of the processed digital signal be consistent with the intensity of the first input signal.

6. The audio processing circuit of claim 1, further comprising:
a zero-crossing detection circuit, arranged to detect a zero-crossing point of the first input signal, a zero-crossing point of the first amplified input signal, or a zero-crossing point of the processed signal, in order to generate a zero-crossing point detection result;
wherein according to the zero-crossing point detection result, the control circuit adjusts the gain value of the first amplifier and the gain value of the processing circuit based on the peak value detection result when the first input signal, the first amplified input signal, or the processed signal is at the zero-crossing point.

7. The audio processing circuit of claim 1, wherein a supply voltage of the first amplifier is higher than a supply voltage of the processing circuit and the analog-to-digital converter.

8. The audio processing circuit of claim 1, further comprising:
a second amplifier, arranged to receive a second input signal, and perform an amplification operation upon the second input signal to generate a second amplified input signal;
wherein the processing circuit performs an addition operation and a signal attenuation operation upon the first amplified input signal and the second amplified input signal, in order to generate the processed signal.

9. The audio processing circuit of claim 8, wherein the control circuit is further arranged to control a gain value of the second amplifier according to the peak value detection result.

10. The audio processing circuit of claim 9, further comprising:
a digital signal processor, coupled to the analog-to-digital converter, and arranged to process the digital signal to generate a processed digital signal;
wherein when the peak value detection result indicates the first amplified input signal, the processed signal, or the digital signal has a first peak value, the control circuit increases the gain value of the first amplifier and the gain value of the second amplifier; and when the peak value detection result indicates the first amplified input signal, the processed signal, or the digital signal has a second peak value higher than the first peak value, the control circuit decreases the gain value of the first amplifier and the gain value of the second amplifier.

11. The audio processing circuit of claim 8, further comprising:
a zero-crossing detection circuit, arranged to detect zero-crossing points of the first input signal and the second input signal, zero-crossing points of the first amplified input signal and the second amplified input signal, or a zero-crossing point of the processed signal, in order to generate a zero-crossing point detection result;
wherein according to the zero-crossing point detection result, the control circuit adjusts the gain value of the first amplifier, the gain value of the second amplifier, and the gain value of the processing circuit based on the peak value detection result when both the first input signal and the second input signal are at the zero-crossing points, both the first amplified input signal and the second amplified input signal are at the zero-crossing points, or the processed signal is at the zero-crossing point.
